(19) United States
(12) Patent Application Publication
(10) Pub. No.: US 2009/0191491 A1
(43) Pub. Date: Jul. 30, 2009

(54) Method of Creating an Image in a Photoresist Laminate

(76) Inventors: John Ganjei, Southbury, CT (US); Daniel J. Hart, Watertown, CT (US); Steven Abbott, Ipswich (GB); Mark Sheldon, Oxon (GB)

Correspondence Address: ARTHUR G. SCHAIER;CARMODY & TORRANCE LLP, 50 LEAVENWORTH STREET, P.O. BOX 1110, WATERBURY, CT, 06721, US

(21) Appl. No.: 12/020,673

(22) Filed: Jan. 28, 2008

(51) Int. Cl. G03F 7/30

(52) U.S. Cl. 430/325

(57) ABSTRACT

A process for creating an image in a dry-film resist laminate. The dry-film resist laminate comprises in order, a peelable top layer, a layer of dry-film resist, a clear or translucent coating layer, and a peelable bottom layer. The top layer is peeled from the laminate and the laminate is applied to a surface using heat and pressure. Thereafter, an image is created in the layer of dry-film resist and the resist is developed to remove uncured portions of the layer of photoresist along with the clear or translucent coating layer.

### FIELD OF THE INVENTION

The present invention relates to an improved process for creating an image in a photoresist laminate material.

### BACKGROUND OF THE INVENTION

Photosensitive compositions that are useful as photoresists are well known in the prior art and can be positive-working or negative-working. The photosensitive composition generally contains a polymeric binder, at least one monomeric or oligomeric material capable of polymerizing and/or cross-linking, and a photoinitiator or photoinitiator system. Exposure to actinic radiation initiates the polymerization and/or crosslinking reactions, resulting in insolubilization of the material in developer solvents. The thus formed latent image is developed by treating with a suitable developer solvent.

The photosensitive composition may be formed as a dry film-photoresist layer on a support. Dry-film photosensitive compositions are typically made by combining the necessary components in a solvent, applying the solvated materials to a transparent carrier, such as a polyester film, and evaporating the solvent. The dried material remaining on the carrier is the dry-film photosensitive material. In the alternative, the photoresist composition maybe extruded onto the carrier. A flexible cover film can be applied over the photosensitive composition to protect the photosensitive material during storage and shipping. The resulting sandwiched dry-film photosensitive material can be stored in roll form until it is ready for use.

The dry-film photosensitive composition is applied to a substrate, such as a copper-clad laminate, typically by laminating with heat and pressure, exposed in selected areas to actinic radiation to cure the film in the selected areas, and then washed with a developer solution, such as an alkaline aqueous solution, to remove the unexposed film from the substrate. If desired, the exposed copper surface can be removed in etching solutions, to leave the protected copper area under the cured photopolymerized composition to form an electrical circuit.

Dry film photoresist laminates are typically used for the production of etch resists for printed circuits and the like. The transfer is performed in such a manner that the bare surfaces of the light-sensitive layer, or the surface bared by the removal of a protective film, is laminated using heat or pressure, to the final support (i.e., copper-clad substrate), and the temporary support, which is typically a transparent film, is removed from the light-sensitive layer after the light-sensitive layer is exposed to light.

For high resolution, it is generally necessary for the resist to be removed cleanly during the development step without leaving any residue on the underlying substrate. It is also important that the photoresist have good adhesion to the substrate, which is usually copper. The board with imaged resist is treated with a variety of chemicals during the manufacturing steps, including etching and/or plating chemistries. Inadequate adhesion of the photoresist to the substrate can result in the chemistries reacting underneath the resist in areas intended to be covered. Thus the quality of the end product is reduced and failures can occur.

Various methods of creating images in dry-film resists are known in the art. However, additional work is needed for creating images in dry-film photoresists to avoid oxygen inhibition which slows curing and to avoid scratching or marring the laminate which can lead to imaging problems. Thus, the present invention relates to an improved method of creating an image in a photoresist laminate that avoids the noted problems of the prior art.

### SUMMARY AND OBJECTS OF THE INVENTION

It is an object of the present invention to create an image in a dry-film resist laminate in a process that avoids oxygen inhibition which slows curing.

It is another object of the present invention to provide a removable layer on a dry-film resist layer that protects the dry-film resist layer to avoid scratching the photoresist layer, which can lead to imaging problems in the laminate.

To that end, the present invention relates generally to a process for creating an image in a photoresist comprising: (1) providing a dry film resist laminate comprising: (a) a top layer which is removable by peeling it from the laminate; (b) a layer of dry film photoresist disposed on the top layer; (c) a clear or translucent coating on top of the dry film photoresist; and (d) a bottom layer disposed on the coating, which bottom layer is removable by peeling it from the laminate; (2) peeling the top layer from the dry film laminate and applying the dry film laminate to a surface using heat and pressure such that the layer of dry film photoresist is adjacent to the surface; (3) peeling the bottom layer from the dry film laminate such that the coating is left exposed on one surface of the layer of dry film photoresist; (4) creating an image in the layer of dry film photoresist by selectively exposing it to laser radiation through the clear or translucent coating such that portions of the layer of dry film photoresist which are exposed to laser radiation are cured but portions which are not exposed to radiation, preferably laser radiation, remain substantially uncured; and (5) selectively removing the uncured portions of the layer of dry film photoresist along with the clear or translucent coating.

### DETAILED DESCRIPTION OF THE PREFERRED EMBODIMENTS

In one embodiment, the present invention relates generally to an improved process for creating an image in a dry-film resist laminate comprising the steps of:
(1) providing a dry film resist laminate comprising:
   a) a top layer which is removable by peeling it from the laminate;
   b) a layer of dry film photoresist disposed on the top layer;
   c) a clear or translucent coating on top of the dry film photoresist; and
   d) a bottom layer disposed on the coating, which bottom layer is removable by peeling it from the laminate;
(2) peeling the top layer from the dry film laminate and applying the dry film laminate to a surface using heat and pressure such that the layer of dry film photoresist is adjacent to the surface;
(3) peeling the bottom layer from the dry film laminate such that the coating is left exposed;
(4) creating an image in the layer of dry film photoresist by selectively exposing it to radiation, preferably laser radiation, through the clear or translucent coating such that portions of the layer of dry film photoresist which are exposed to the radiation are cured but portions which are not exposed to the radiation remain substantially uncured; and
(5) selectively removing the uncured portions of the layer of dry film photoresist along with the clear or translucent coating thereon.

The top layer of the dry film laminate is a peelable layer that protects the photoresist layer during storage and may comprise treated cellulose, paper, polyolefin resins, polyester resins, and polyvinylchloride resins. Preferred examples include polyethylene, polypropylene and polyethylene terephalate polyester (e.g., Mylar®) sheets.

A clear or translucent layer is deposited on top of the dry film photoresist layer. The clear or translucent layer typically comprises a water removable coating layer, including for example materials that are starch-based, polymeric, such as polyvinyl alcohol, carboxymethyl cellulose, polyvinyl pyridine, polyethylene oxide or water dispersible or soluble polymers. In a preferred embodiment, the clear or translucent layer is polyvinyl alcohol. The purpose of the clear or translucent layer is to protect the photoresist layer from scratching or other damage. The clear or translucent layer also serves to inhibit oxygen from diffusing into the photoresist layer after the bottom layer is peeled away. Oxygen diffusion into the photoresist slows the curing process because the presence of oxygen in the photoresist inhibits polymerization. This is a particular problem when imaging with a laser, since laser imaging occurs in the presence of air. In contrast, imaging using a phototool generally occurs in a vacuum since a vacuum is used to hold the phototool to the face of the photoresist and thus oxygen inhibition is not a problem here. Further when imaging with a laser it is critical for polymerization speed to be as high as possible so that the laser can quickly scan the photoresist.

Finally, a bottom layer is dispose on top of the clear or translucent coating. This bottom layer is also removable by peeling. In one embodiment, the bottom layer comprises the same or similar materials as are used for the top layer.

The layer of dry-film photoresist is typically an aqueous-developable dry-film photosensitive composition. Dry-film photosensitive compositions are generally well known in the art. As used herein the term “dry” films refers to those films in which the solvent has been evaporated and which exhibit solid, semi-solid or which have plastic flow properties.

In one embodiment, the photosensitive composition includes a carboxyl group-containing, film-forming polymeric binder, a free-radical photoinitiator, a polyfunctional addition-polymerizable monomer, a plasticizer, and a thermal polymerization inhibitor in addition to other additives, as would generally be well known to those skilled in the art.

Film-forming polymeric binders usable in the photosensitive composition may be prepared from one or more film-forming, vinyl type monomers and one or more alpha, beta-ethylenically unsaturated carboxyl group containing monomers having 3-15 carbon atoms, which makes the binder soluble in aqueous media. Examples of useful vinyl type monomers are alkyl and hydroxyalkyl acrylates and methacrylates having 3-15 carbon atoms, styrene, and alkyl substituted styrenes. The acrylates and methacrylates are preferred. Examples of useful carboxyl group-containing monomers are cinnamic acid, crotonic acid, sorbic acid, acrylic acid, methacrylic acid, itaconic acid, propiolic acid, maleic acid, fumaric acid, and half esters and anhydrides of these acids. Acrylic acid and methacrylic acid are preferred. Other useful binders will be apparent to those skilled in the art.

The free-radical photoinitiator useful in accordance with this invention is a conventional photoinitiator activatable by actinic radiation that is thermally inactive below about 185° C. Examples of useful photoinitiators include aromatic ketones, such as benzophenone and dimethoxyphenyl acetophenone. Other photoinitiators would also be well known to those skilled in the art.

The polyfunctional addition-polymerizable monomer that finds application in the subject invention is nongaseous, contains at least 2, preferably 2 to 4, more preferably 2 to 3 ethylenic double bonds. Having at least 2 ethylenic double bonds makes the monomer polyfunctional, i.e., capable of cross-linked polymerization. Suitable monomers include alkylene or polyalkylene glycol diacrylates. Non-limiting examples include but are not limited to ethylene diacrylate; diethylene glycol diacrylate; glycerol diacrylate; glycerol triacrylate; 1,3-propanediol dimethacrylate; 1,2,4-butanetriol trimethacrylate; 1,4-benzenediol dimethacrylate; 1,4-cyclohexanediol diacrylate; pentaerythritol tri- and tetramethacrylate; pentaerythritol tri- and tetraacrylate; tetraethylene glycol dimethacrylate; trimethylolpropane trimethacrylate; triethylene glycol diacrylate; tetraethylene glycol diacrylate; pentaerythritol triacrylate; trimethylol propane triacrylate; pentaerythritol tetraacrylate; 1,3-propanediol diacrylate; 1,5-pentanediol dimethacrylate; and the bis-acrylates and bis-methacrylates of polyethylene glycols, polypropylene glycols, and copolymers thereof of molecular weight from about 100 to about 500 (number average). Other useful polymerizable monomers will be apparent to those skilled in the art.

The photoresist compositions may also contain plasticizer components that help in providing resiliency and adhesion to the layers, and which permit the layers to resist flaking and delamination during use. Any plasticizer which does not interfere significantly with the photoimaging and photohardening of the polymeric material may be used in the photosensitive, adhesive layer or film. A representative, non-limiting list of such materials includes phthalates, benzoates, phosphates, adipates, sebacate esters, and polyols such as ethylene glycol and its derivatives. Other plasticizers include tri-n-butyl citrate, N-ethyl-toluene sulfonamide, and glycerol triacetate, as well as polymeric materials such as carboxyl-modified polyurethanes.

A thermal polymerization inhibitor may be included in the photoresist composition of the invention and is used to prevent thermal polymerization during drying and storage. Examples of useful thermal polymerization inhibitors are p-methoxyphenol, hydroquinone, alkyl and aryl-substituted hydroquinones and quinones, terbutyl catechol, pyrogallol, copper resinate, β-naphthol, 2,6-di-tert-butyl-p-cresol, 2,2′-methylene-bis(4-ethyl-6-t-butylphenol), p-tolylquinone, chloranil, aryl phosphites, and aryl alkyl phosphites. Other useful thermal polymerization inhibitors will be apparent to those skilled in the art.

Finally, the photosensitive composition may include other additives well known in the art of photosensitive compositions, including leuco (i.e., printout) dyes, background dyes, adhesion promoters, and antioxidants. Other optional additives would also be generally well known to those skilled in the art.

The photosensitive composition is prepared by mixing the various components in a solvent. Suitable solvents include alcohols, ketones, halogenated hydrocarbons, and ethers. Other solvents would also be known to those skilled in the art. After mixing, the composition is coated onto a support or carrier, and the solvent is evaporated.

After the top layer is removed, the layer of dry film photoresist is typically laminated to a pre-cleaned copper or a copper-plated support material. The dry film photoresist may also be laminated to other support materials as is well known in the art. The photoresist is laminated using heat and/or pressure, such as with a conventional hot-roll laminator, as described for example in U.S. Pat. No. 4,293,635 to Flint et al., the subject matter of which is herein incorporated by reference in its entirety.

Once the bottom layer is removed from the photoresist laminate, the photoresist layer is selectively exposed to actinic radiation to create a latent image of photosensitive material, and developed in a developing solution to remove the unpolymerized composition from the copper surface along with the clear or translucent coating. The step of selectively exposing the photoresist layer to actinic radiation typically involves exposing the photoresist to radiation, which may preferably be laser radiation, such that areas exposed to radiation are cured and portions that are not exposed to radiation remain substantially uncured and can be removed in the subsequent development step. Use of a laser allows the resist to be exposed without a mask by writing the controlled laser beam directly on the resist layer. Suitable sources of laser light include lasers that emit light at a wavelength of between about 350 nm and 450 nm, including for example argon ion lasers, krypton ion lasers, argon ion UV lasers, solid state UV lasers, and violet lasers, among others. Other suitable layers would also be known to those skilled in the art. If non-laser radiation is used then a mask or phototool must be used to achieve selective exposure.

The portions of the surface not covered by the photopolymerized material may be modifiable by known processes, e.g., by plating or etching procedures, while the photoresist protects the covered surface. If desired, the photopolymerized material can be ultimately removed from the substrate by washing with known stripping solutions.

The copper clad substrate may be any known copper/dielectric laminate used in circuit board manufacture, such as a copper clad board of fiberglass reinforced epoxy resin. Other useful dielectrics will be apparent to those skilled in the art.

The developing solution usable in the process of the invention is typically an aqueous developing solution comprising about 0.5-10% by weight alkaline agents, preferably about 0.5-1% by weight, and the latent imaged board is washed in the solution for a time sufficient to remove the unpolymerized composition. Suitable alkaline agents include alkali metal hydroxides, such as lithium, sodium and potassium hydroxide, base reacting alkali metal salts of weak acids, e.g., sodium carbonate and bicarbonate, and alkali metal phosphates and pyrophosphates. The substrate can be submerged in the developing solution or the solution may be high pressure sprayed onto the substrate.

The process of the invention produces an image in the dry film laminate that overcomes problems with oxygen inhibition and damage to the photoresist layer noted in the prior art.

While the invention has been described above with reference to specific embodiments thereof, it is apparent that many changes, modifications, and variations can be made without departing from the inventive concept disclosed here. Accordingly, it is intended to embrace all such changes, modifications, and variations that fall within the spirit and broad scope of the appended claims. All patent applications, patents, and other publications cited herein are incorporated by reference in their entirety.

What is claimed is:

1. A process for creating an image comprising the steps of:
(1) providing a dry film resist laminate comprising:
a) a top layer which is removable by peeling it from the laminate;
b) a layer of dry film photoresist on top of the top layer;
c) a clear or translucent coating on top of the dry film photoresist; and
d) a bottom layer on top of the coating, which bottom layer is removable by peeling it from the laminate;
(2) peeling the top layer from the dry film laminate and applying the dry film laminate to a surface using heat and pressure such that the layer of dry film photoresist is adjacent to the surface;
(3) peeling the bottom layer from the dry film laminate such that the coating is left exposed;
(4) creating an image in the layer of dry film photoresist by selectively exposing it to laser radiation such that portions of the layer of dry film photoresist which are exposed to laser radiation are cured but portions which are not exposed to laser radiation remain substantially uncured; and
(5) selectively removing the uncured portions of the layer of dry film photoresist.

2. The method according to claim 1, wherein the clear or translucent coating is polyvinyl alcohol.

3. The method according to claim 1, wherein the step of removing the uncured portions of the layer of dry film resist also removes the clear or translucent coating.

4. The method according to claim 1, wherein the step of selectively removing the uncured portion comprises washing the layer of dry film photoresist with an aqueous alkaline solution to remove the uncured portion.

5. The method according to claim 1, wherein the surface comprises a copper clad laminate.

6. The method according to claim 1, wherein the top layer comprises a material selected from the group consisting of treated cellulose, paper, polyolefin resins, polyester resins, and polyvinylchloride resins.

7. The method according to claim 1, wherein the bottom layer comprises a material selected from the group consisting of treated cellulose, paper, polyolefin resins, polyester resins, and polyvinylchloride resins.

8. The method according to claim 1, wherein the laser emits light at a wavelength of between about 350 and about 450 nm.
